(19) United States
(12) Patent Application Publication
(10) Pub. No.: US 2025/0122625 A1
(43) Pub. Date: Apr. 17, 2025

(54) SUBSTRATE PROCESSING APPARATUS

(71) Applicant: TOKYO ELECTRON LIMITED, Tokyo (JP)

(72) Inventors: Motoi YAMAGATA, Tokyo (JP); Hiroshi SONE, Tokyo (JP); Masato SHINADA, Tokyo (JP); Yusuke KIKUCHI, Yamanashi (JP)

(21) Appl. No.: 18/834,129

(22) PCT Filed: Jan. 25, 2023
(86) PCT No.: PCT/JP2023/002250

§ 371 Date: Jul. 29, 2024

(30) Foreign Application Priority Data
Feb. 1, 2022 (JP) 2022-014450

(51) Int. Cl. C23C 16/46

(52) U.S. Cl. CPC C23C 16/463

(57) ABSTRACT

Provided is a substrate processing apparatus that has an improved cooling performance. This substrate processing apparatus comprises: a placing table which is provided in a processing container and on which a substrate is to be placed; a refrigerator that has a contacting surface that makes contact with or is separated from a contact target surface of the placing table, and cools the placing table; and a lifting/lowering device that lifts or lowers the refrigerator and generates a pressing force for pressing the refrigerator against the placing table.

### TECHNICAL FIELD

The present disclosure relates to a substrate processing apparatus.

### BACKGROUND

Patent Document 1 discloses a substrate processing apparatus including: a processing chamber in which a placing table on which a substrate is placed and a target holder for holding a target are disposed, a freezing device having a gap between itself and a bottom surface of the placing table and including a refrigerator and a refrigeration medium stacked on the freezing machine, a rotation device for rotating the placing table, a first lifting/lowering device for lifting and lowering the placing table, a coolant channel that is disposed in the freezing device and supplies a coolant to the gap, and a cold heat transfer material disposed in the gap and in contact with both the placing table and the refrigeration medium to be thermally conductive.

### PRIOR ART DOCUMENTS

### Patent Documents

Patent document 1: Japanese Laid-open Patent Publication No. 2021-139017

### SUMMARY

### Problems to be Resolved by the Invention

One aspect of the present disclosure provides a substrate processing apparatus for improving cooling performance.

### Means for Solving the Problems

In accordance with an aspect of the present disclosure, there is provided a substrate processing apparatus comprising: a placing table disposed in a processing chamber and on which a substrate is placed; a freezing device having a contact surface that is brought into contact with or is separated from a surface to be contacted of the placing table, and configured to cool the placing table; and a lifting/lowering device configured to raise and lower the freezing device and generate a pressing force for pressing the freezing device against the placing table.

### Effect of the Invention

In accordance with one aspect of the present disclosure, it is possible to provide a substrate processing apparatus for improving cooling performance.

### BRIEF DESCRIPTION OF THE DRAWINGS

FIG. 1 is a cross-sectional view showing an example of a configuration of a substrate processing apparatus according to an embodiment during rotation of a placing table.

FIG. 2 is a cross-sectional view showing an example of a configuration of the substrate processing apparatus according to the embodiment during cooling of the placing table.

FIG. 3 is a graph showing an example of temperature changes of the placing table.

FIG. 4 is a cross-sectional view showing a configuration of an example of a support structure of the placing table during the rotation of the placing table.

FIG. 5 is a cross-sectional view showing a configuration of an example of the support structure of the placing table during the cooling of the placing table.

FIG. 6 is a cross-sectional view showing a configuration of an example of a support structure of a placing table in a reference example.

FIG. 7 is a cross-sectional view showing a configuration of an example of a pressing biasing structure of the placing table.

### DETAILED DESCRIPTION

Hereinafter, embodiments for implementing the present disclosure will be described with reference to the accompanying drawings. Like reference numerals will be used for like parts throughout the drawings, and redundant description thereof may be omitted.

### Substrate Processing Apparatus 1

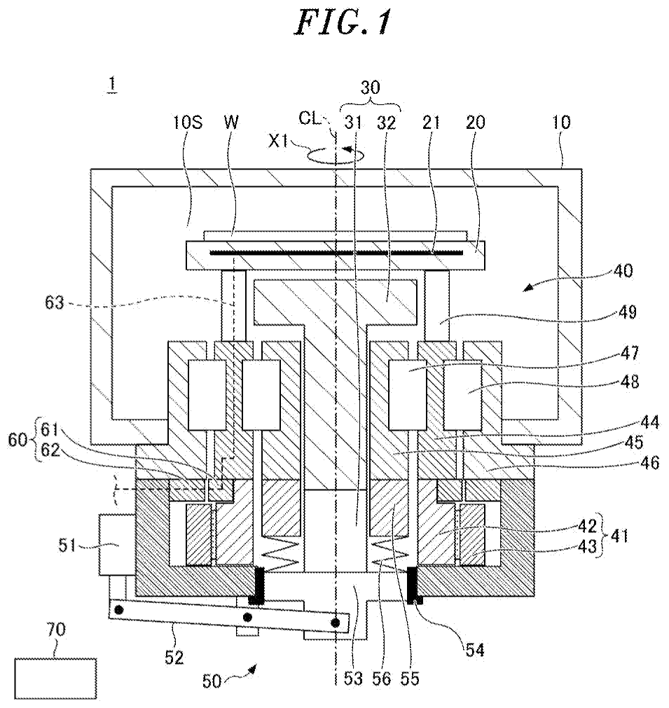

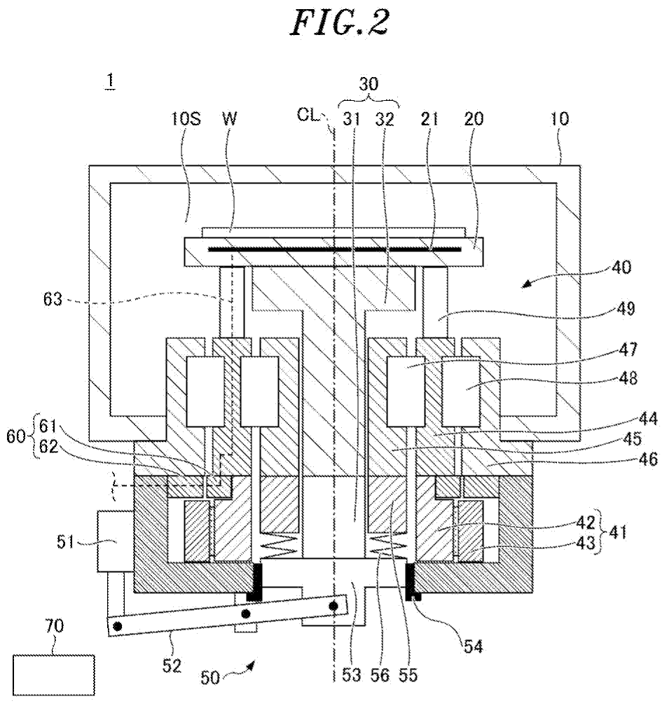

An example of the substrate processing apparatus 1 according to an embodiment will be described with reference to FIGS. 1 and 2. FIG. 1 is a cross-sectional view showing an example of a configuration of a substrate processing apparatus 1 according to an embodiment during rotation of a placing table 20. FIG. 2 is a cross-sectional view showing an example of the configuration of the substrate processing apparatus 1 during cooling of the placing table 20.

The substrate processing apparatus 1 may be a substrate processing apparatus (e.g., a chemical vapor deposition (CVD) apparatus, an atomic layer deposition (ALD) apparatus, or the like) for performing desired processing on a substrate W by supplying a processing gas into a processing chamber 10, for example. Further, the substrate processing apparatus 1 may be a substrate processing apparatus (e.g., a physical vapor deposition (PVD) apparatus or the like) for performing desired processing (e.g., film formation) on the substrate W by supplying a processing gas into the processing chamber 10 and sputtering a target disposed in the processing chamber 10, for example.

The substrate processing apparatus 1 includes the processing chamber 10, the placing table 20 on which a substrate W is placed in the processing chamber 10, a freezing device 30, a rotation device 40 for rotating the placing table 20, and a lifting/lowering device 50 for lifting and lowering the freezing device 30. The substrate processing apparatus 1 further includes a slip ring 60 for supplying a power to a chuck electrode 21 of the placing table 20 that is rotating. The substrate processing apparatus 1 further includes a controller 70 for controlling various devices such as the freezing device 30, the rotation device 40, and the lifting/lowering device 50.

The processing chamber 10 defines an inner space 10S. The processing chamber 10 is configured such that the inner space 10S is depressurized to an ultra-high vacuum by operating an exhaust device (not shown) such as a vacuum pump or the like. Further, a desired gas used for substrate processing is supplied into the processing chamber 10 through a gas supply line (not shown) communicating with a processing gas supply device (not shown).

The placing table 20 on which the substrate W is placed is disposed in the processing chamber 10. The placing table 20 is made of a material with high thermal conductivity (e.g., Cu). The placing table 20 includes an electrostatic chuck. The electrostatic chuck has a chuck electrode 21 embedded in a dielectric film. A predetermined potential is supplied to the chuck electrode 21 via a slip ring 60 and a wiring 63 that will be described later. With this configuration, the substrate W can be attracted to the electrostatic chuck and fixed to the upper surface of the placing table 20.

The freezing device 30 is disposed below the placing table 20. The freezing device 30 is formed by stacking a refrigerator 31 and a refrigeration medium 32. The refrigeration medium 32 can also be referred to as a cold link. The refrigerator 31 holds the refrigeration medium 32, and cools the upper surface of the refrigeration medium 32 to an extremely low temperature. In view of cooling performance, the refrigerator 31 preferably uses a Gifford-McMahon (GM) cycle. The refrigeration medium 32 is fixed on the refrigerator 31, and the upper part thereof is accommodated in the processing chamber 10. The refrigeration medium 32 is made of a material having high thermal conductivity (for example, Cu), and has a substantially cylindrical outer shape. The refrigeration medium 32 is disposed such the center thereof coincides with a central axis CL of the placing table 20.

Further, the placing table 20 is rotatably supported by the rotation device 40. The rotation device 40 includes a rotation driving device 41, a fixed shaft 45, a rotation shaft 44, a housing 46, magnetic fluid seals 47 and 48, and a stand 49.

The rotational driving device 41 is a direct drive motor having a rotor 42 and a stator 43. The rotor 42 has a substantially cylindrical shape extending coaxially with the rotation shaft 44, and is fixed to the rotation shaft 44. The stator 43 has a substantially cylindrical shape with an inner diameter larger than the outer diameter of the rotor 42. The rotational driving device 41 may be in a form other than a direct drive motor, or may be in a form including a servomotor and a transmission belt.

The rotation shaft 44 has a substantially cylindrical shape extending coaxially with the central axis CL of the placing table 20. The fixed shaft 45 is provided inside the rotation shaft 44 in a radial direction. The fixed shaft 45 has a substantially cylindrical shape extending coaxially with the central axis CL of the placing table 20. The housing 46 is provided outside the rotation shaft 44 in the radial direction. The housing 46 has a substantially cylindrical shape extending coaxially with the central axis CL of the placing table 20 and is fixed to the processing chamber 10.

Further, the magnetic fluid seal 47 is provided between the outer peripheral surface of the fixed shaft 45 and the inner peripheral circumference of the rotation shaft 44. The magnetic fluid seal 47 rotatably supports the rotation shaft 44 with respect to the fixed shaft 45, and seals the gap between the outer peripheral surface of the fixed shaft 45 and the inner circumference of the rotation shaft 44 to separate the inner space 10S of the depressurizable processing chamber 10 from the outer space of the processing chamber 10. Further, the magnetic fluid seal 48 is provided between the inner peripheral surface of the housing 46 and the outer circumference of the rotation shaft 44. The magnetic fluid seal 48 rotatably supports the rotation shaft 44 with respect to the housing 46, and seals the gap between the inner peripheral surface of the housing 46 and the outer circumference of the rotation shaft 44 to separate the inner space 10S of the depressurizable processing chamber 10 from the outer space of the processing chamber 10. Accordingly, the rotation shaft 44 is rotatably supported by the fixed shaft 45 and the housing 46.

Further, the refrigeration medium 32 is inserted through the radially inner side of the fixed shaft 45.

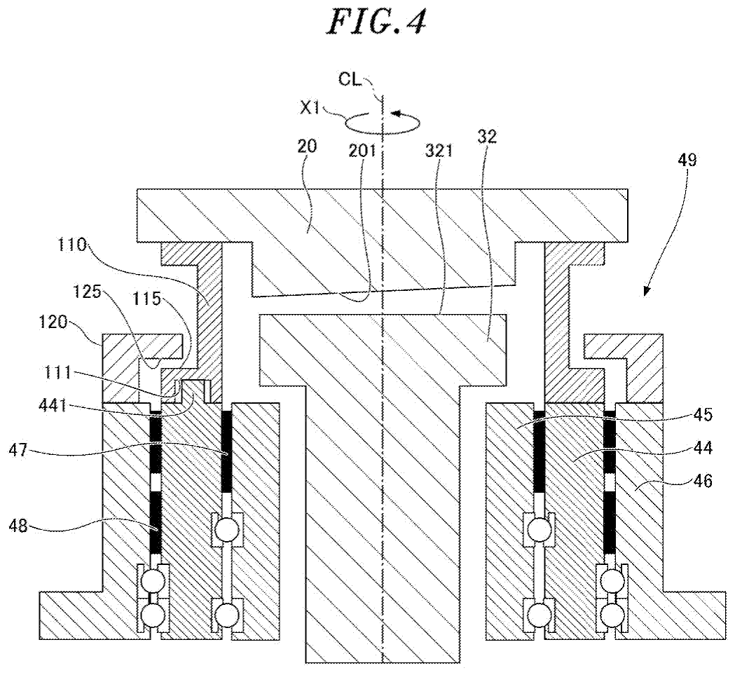

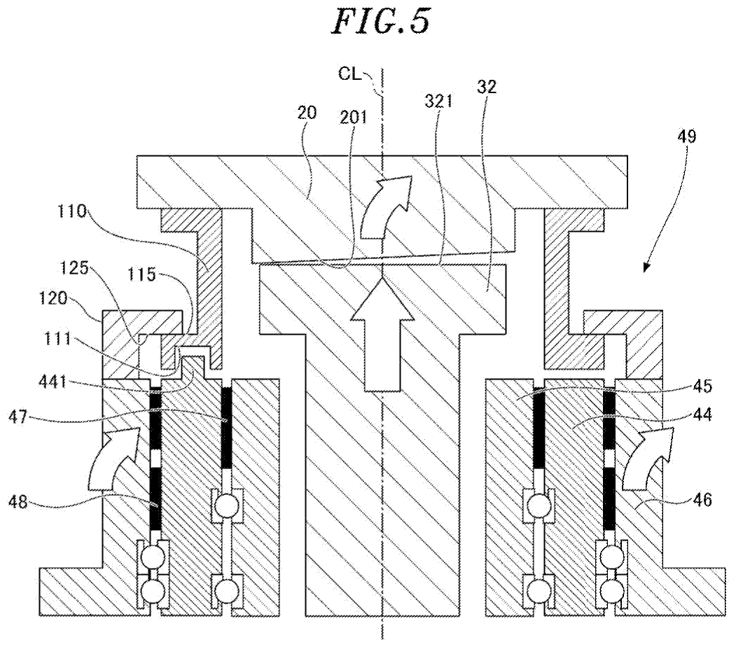

The stand 49 is provided between the rotation shaft 44 and the placing table 20, and is configured to transmit the rotation of the rotation shaft 44 to the stand 49. The structure of the stand 49 will be described later with reference to FIGS. 4 and 5.

With the above configuration, when the rotor 42 of the rotation driving device 41 rotates, the rotation shaft 44, the stand 49, and the placing table 20 rotate relative to the refrigeration medium 32 in the X1 direction.

Further, the freezing device 30 is supported by the lifting/lowering device 50 to be vertically movable. The lifting/lowering device 50 includes an air cylinder 51, a link mechanism 52, a freezing device support 53, a linear guide 54, a fixed portion 55, and a bellows 56.

The air cylinder 51 is a mechanical device whose rod moves linearly by air pressure. The link mechanism 52 converts the linear motion of the rod of the air cylinder 51 into vertical motion of the freezing device support 53. Further, the link mechanism 52 has a lever structure, one end of which is connected to the air cylinder 51 and the other end of which is connected to the freezing device support 53. Accordingly, a large pressing force can be generated with a small thrust of the air cylinder 51. The freezing device support 53 supports the freezing device 30 (the refrigerator 31 and the refrigeration medium 32). Further, the moving direction of the freezing device support 53 is guided in the vertical direction by the linear guide 54.

The fixed portion 55 is fixed to the bottom surface of the fixed shaft 45. The substantially cylindrical bellows 56 surrounding the refrigerator 31 is provided between the bottom surface of the fixed portion 55 and the upper surface of the freezing device support 53. The bellows 56 is a metal bellows structure that is vertically extensible and contractible. Accordingly, the fixed portion 55, the bellows 56, and the freezing device support 53 seal the gap between the inner peripheral surface of the fixed shaft 45 and the outer circumference of the refrigeration medium 32 to separate the inner space 10S of the processing chamber 10 from the outer space of the processing chamber 10. Further, the bottom surface side of the freezing device support 53 is adjacent to the outer space of the processing chamber 10, and the region surrounded by the bellows 56 on the upper surface side of the freezing device support 53 is adjacent to the inner space 10S of the processing chamber 10.

The slip ring 60 is provided below the rotation shaft 44 and the housing 46. The slip ring 60 has a rotating body 61 including a metal ring and a fixed body 62 including a brush. The rotating body 61 has a substantially cylindrical shape extending coaxially with the rotation shaft 44, and is fixed to the bottom surface of the rotation shaft 44. The fixed body 62 has a substantially cylindrical shape with an inner diameter slightly larger than an outer diameter of the rotating body 61, and is fixed to the bottom surface of the housing 46. The slip ring 60 is electrically connected to a DC power supply (not shown), and supplies a power from the DC power supply to the wiring 63 via the brush of the fixed body 62 and the metal ring of the rotating body 61. With this configuration, a potential can be applied from the DC power supply to the chuck electrode 21 without twisting the wiring 63. The structure of the slip ring 60 may be a structure other than the brush structure, for example, a contactless power supply structure, a mercury-free structure, a structure containing a conductive liquid, or the like.

The controller 70 is, e.g., a computer, and includes a central processing unit (CPU), a random access memory (RAM), a read only memory (ROM), an auxiliary storage device, and the like. The CPU operates based on a program stored in the ROM or the auxiliary storage device to controls the operation of the substrate processing apparatus 1. The controller 70 may be installed inside the substrate processing apparatus 1, or may be installed outside the substrate processing apparatus 1. When the controller 70 is provided outside the substrate processing apparatus 1, the controller 70 can control the substrate processing apparatus 1 using a wired or wireless communication device.

In the case of performing desired processing on the substrate W, as shown in FIG. 1, the controller 70 controls the lifting/lowering device 50 (the air cylinder 51) to separate the placing table 20 and the refrigeration medium 32, and controls the rotation device 40 (the rotation driving device 41) to rotate the placing table 20 on which the substrate W is placed. Accordingly, the in-plane uniformity of substrate processing (e.g., film formation or the like) of the substrate W can be improved.

Further, in the case of cooling the placing table 20 and the substrate W placed on the placing table 20, as shown in FIG. 2, the controller 70 stops the rotation device 40 (the rotation driving device 41) to stop the rotation of the placing table 20, and controls the lifting/lowering device 50 (the air cylinder 51) to bring the placing table 20 and the refrigeration medium 32 into contact with each other. Accordingly, the substrate W placed on the placing table 20 can be cooled.

Here, if the pressing force for pressing the refrigeration medium 32 against the placing table 20 is insufficient, loss occurs in heat conduction, and the cooling performance for the placing table 20 is insufficient.

On the other hand, in the substrate processing apparatus 1, the upper surface (contact surface) of the refrigeration medium 32 is in direct contact with the bottom surface (surface to be contacted) of the placing table 20, and the refrigeration medium 32 is brought into contact with the placing table 20 and stops. Accordingly, the refrigeration medium 32 is in direct contact with the placing table 20, so that the cooling performance for the placing table 20 can be improved.

Further, by depressurizing the inner space 10S of the processing chamber 10 to a vacuum atmosphere, a pressure difference (vacuum pressure difference) is generated between the upper surface of the freezing device support 53 in a vacuum atmosphere and the bottom surface of the freezing device support 53 in an atmospheric atmosphere, which generates a pressing force for pressing the refrigeration medium 32 against the placing table 20. Therefore, the pressing force is applied to the refrigeration medium 32 by the thrust of the air cylinder 51 and the pressure difference (vacuum pressure difference) generated between the upper surface and the bottom surface of the freezing device support 53. Accordingly, when the refrigeration medium 32 is brought into contact with the placing table 20 to cool the placing table 20, even if the placing table 20 is thermally contracted, the refrigeration medium 32 may be raised to correspond to the thermal contraction of the placing table 20 by the pressing force.

Further, the vertical movement of the refrigeration medium 32 is guided by the freezing device support 53 and the linear guide 54. Accordingly, the refrigeration medium 32 can be raised and lowered in a state where the bottom surface (the surface to be contacted) of the placing table 20 and the upper surface (the contact surface) of the refrigeration medium 32 are maintained to be parallel to each other.

Further, a shim (not shown) is inserted into the refrigeration medium 32 to adjust a degree of parallel of the upper surface (the contact surface) of the refrigeration medium 32 with respect to the bottom surface (the surface to be contacted) of the placing table 20.

Further, since the air cylinder 51 that is driven by air is used, the pressing force can be easily adjusted using an air pressure.

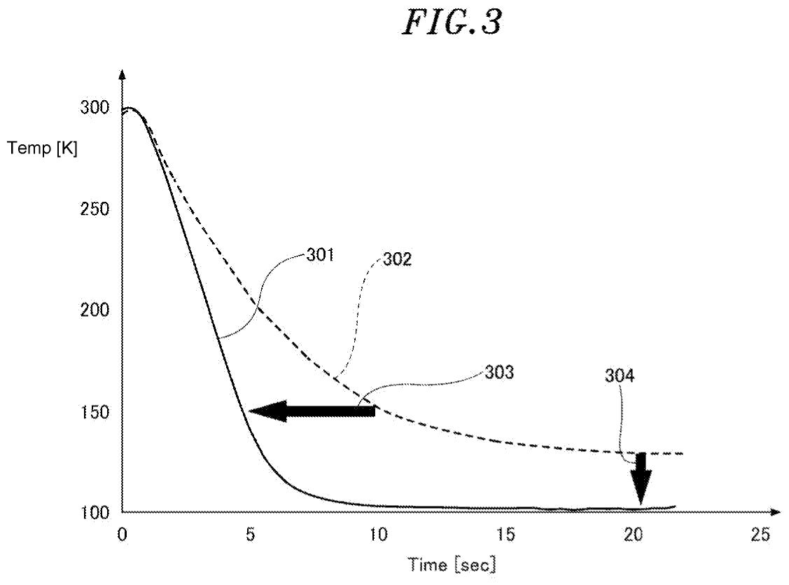

FIG. 3 is a graph showing an example of temperature changes of the placing table 20. The horizontal axis represents time elapsed after the refrigeration medium 32 is brought into contact with the placing table 20. The vertical axis represents the temperature of the placing table 20. Further, a solid line 301 indicates the temperature change of the placing table 20 in the substrate processing apparatus 1 according to the embodiment shown in FIGS. 1 and 2. The temperature change of the placing table in the substrate processing apparatus according to a first reference example is indicated by a dashed line 302.

Here, in the substrate processing apparatus of the first reference example, an elastically deformable heat conductive member such as a spring is provided between the placing table and the refrigeration medium. Further, a linear motion mechanism capable of controlling a stroke amount, such as a ball screw or the like, is used as the lifting/lowering device for lifting and lowering the freezing device. In the case of cooling the placing table, the refrigeration medium is raised by a predetermined stroke amount. The repulsive force of the heat conductive member elastically deformed between the placing table and the refrigeration medium is used as the pressing force. In the substrate processing apparatus according to the first reference example, the placing table is cooled from the refrigeration medium through the heat conductive member.

In the substrate processing apparatus of the first reference example, the heat transfer property may be insufficient due to an insufficient pressing force. Further, when the placing table is cooled and contracted, the pressing force may further decrease, and the heat transfer property may deteriorate.

On the other hand, in accordance with the substrate processing apparatus 1 according to an embodiment, the cooling time required to reach a predetermined temperature can be shortened as indicated by an arrow 303. Further, in accordance with the substrate processing apparatus 1 according to an embodiment, the cooling temperature of the placing table 20 can be lowered, as indicated by an arrow 304. In this manner, in accordance with the substrate processing apparatus 1 according to one embodiment, the cooling performance of the placing table 20 can be improved compared to the substrate processing apparatus of the first reference example.

Next, the structure of the stand 49 will be further described with reference to FIGS. 4 and 5. FIG. 4 is a cross-sectional view showing a configuration of an example of a support structure of the placing table 20 during rotation of the placing table 20. FIG. 5 is a cross-sectional view showing a configuration of an example of a support structure of the placing table 20 during cooling of the placing table 20.

The stand 49 includes a support member 110 and a locking member 120.

A plurality of support members 110, e.g., columnar members, are installed in a circumferential direction of the placing table 20. The upper portions of the support members 110 are fixed to the placing table 20. The lower portions of the support members 110 are placed on the rotation shaft 44. Here, a protrusion 441 is formed at the placing surface of the rotation shaft 44 on which the support member 110 is placed. Further, a recess 111 to be engaged with the protrusion 441 is formed at the bottom surface of the support member 110. Further, the support member 110 has a locking portion 115.

The locking member 120 is fixed to the housing 46. Further, the locking member 120 has a locking portion 125.

As shown in FIG. 4, in a state where the surface to be contacted 201 of the placing table 20 and the contact surface 321 of the refrigeration medium 32 are separated, the protrusion 441 formed at the upper end of the rotation shaft 44 is engaged with the recess 111 formed at the lower end of the support member 110. Accordingly, the rotation driving device 41 rotates the rotation shaft 44, so that the stand 49 (the support member 110) transmits the rotational driving force to the placing table 20, and the placing table 20 rotates.

On the other hand, as shown in FIG. 5, in a state where the contact surface 321 of the refrigeration medium 32 presses the surface to be contacted 201 of the placing table 20, the placing surface of the rotation shaft 44 and the bottom surface of the support member 110 are separated. Then, the locking portion 115 of the support member 110 is locked to the locking portion 115 of the locking member 120.

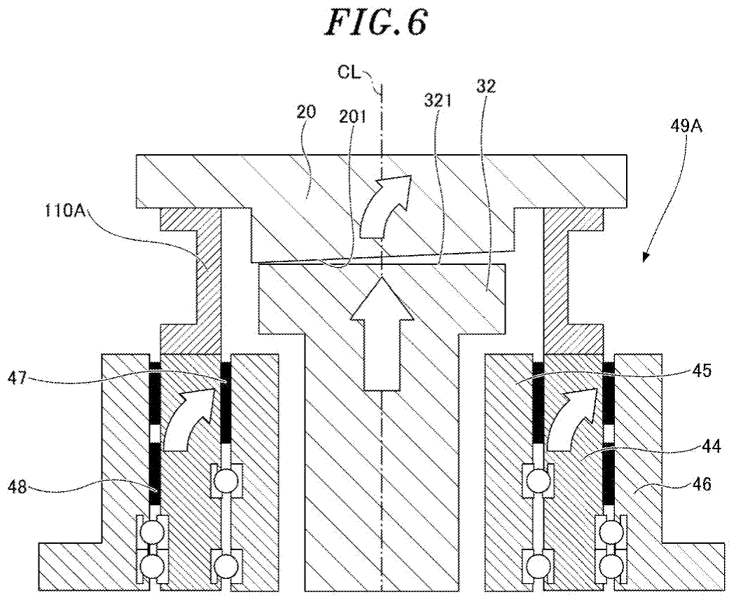

Here, a substrate processing apparatus of a second reference example will be described with reference to FIG. 6. FIG. 6 is a cross-sectional view showing a configuration of an example of a support structure of the placing table 20 in the second reference example. In the support structure of the placing table 20 shown in FIG. 6, a stand 49A has a support member 110A, and the upper portion of the support member 110A is fixed to the placing table 20 and the lower portion of the support member 110A is fixed to the rotation shaft 44.

Therefore, when the refrigeration medium 32 is pressed against the placing table 20, a load is applied to the rotation shaft 44 via the support member 110A. Further, when the surface to be contacted 201 of the placing table 20 and the contact surface 321 of the refrigeration medium 32 are not parallel, the placing table 20 receives an inclined load from the refrigeration medium 32. Hence, the rotation shaft 44 may be inclined and brought into contact with the fixed shaft 45 or the housing 46, or the sealing performance of the magnetic fluid seals 47 and 48 may deteriorate, which may result in breakage of vacuum in the inner space 10S.

On the other hand, as shown in FIG. 5, in the substrate processing apparatus 1 according to an embodiment, when the refrigeration medium 32 is pressed against the placing table 20, the support members 110 are separated from the rotation shaft 44, and the support members 110 are locked to the locking member 120. Thus, when the refrigeration medium 32 is pressed against the placing table 20, a load is applied to the housing 46 fixed to the processing chamber 10 via the support members 110 and the locking member 120. Accordingly, it is possible to prevent the rotation shaft 44 from being inclined and brought into contact with the fixed shaft 45 and the housing 46, and also prevent the sealing performance of the magnetic fluid seals 47 and 48 from deteriorating and causing breakage of vacuum in the inner space 10S.

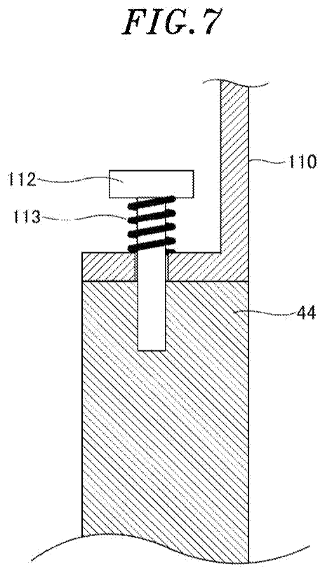

FIG. 7 is a cross-sectional view showing a configuration of an example of a biasing structure of the placing table 20. The biasing structure of the placing table 20 includes, e.g., a shaft member 112 and a biasing member 113. The shaft member 112 has a shaft portion and a head portion whose diameter is larger than that of the shaft portion, and the shaft portion is inserted into the support member 110 and fixed to the rotation shaft 44. The biasing member 113, e.g., a compression spring, is disposed between the head portion of the shaft member 112 and the support member 110, and presses the support member 110 toward the rotation shaft 44.

Accordingly, the support member 110 is pressed against the rotation shaft 44 by the biasing member 113 in a state where the surface to be contacted 201 of the placing table 20 and the contact surface 321 of the refrigeration medium 32 are separated (see FIG. 4). On the other hand, in a state where the contact surface 321 of the refrigeration medium 32 presses against the surface to be contacted 201 of the placing table 20 (see FIG. 5), the biasing member 113 is elastically deformed to separate the rotation shaft 44 and the support member 110.

While the substrate processing apparatus 1 has been described above, the present disclosure is not limited to the above embodiments, and various changes and improvements can be made without departing from the scope of the appended claims and the gist thereof.

This application claims priority to Japanese Patent Application No. 2022-14450 filed on Feb. 1, 2022, the entire contents of which are incorporated herein by reference.

### DESCRIPTION OF REFERENCE NUMERALS

W: substrate
CL: central axis
1: substrate processing apparatus
10: processing chamber
10S: inner space
20: placing table
21: chuck electrode
30: freezing device
31: refrigerator
32: refrigeration medium
40: rotation device
41: rotation driving device
42: rotor
43: stator
44: rotation shaft
45: fixed shaft
46: housing
47, 48: magnetic fluid seal
49: stand
50: lifting/lowering device
51: air cylinder
52: link mechanism
53: freezing device support
54: linear guide
55: fixed portion
56: bellows
60: slip ring
61: rotating body
62: fixed body
63: wiring
70: controller
110: support member
111: recess
441: protrusion
120: locking member
115: locking portion
125: locking portion
201: surface to be contacted
321: contact surface

1. A substrate processing apparatus comprising:
a placing table disposed in a processing chamber and on which a substrate is placed;
a freezing device having a contact surface that is brought into contact with or is separated from a surface to be contacted of the placing table, and configured to cool the placing table; and
a lifting/lowering device configured to raise and lower the freezing device and generate a first pressing force for pressing the freezing device against the placing table.

2. The substrate processing apparatus of claim 1, wherein a second pressing force for pressing the freezing device against the placing table is generated by a pressure difference between an inner space and an outer space of the processing chamber.

3. The substrate processing apparatus of claim 1, wherein the lifting/lowering device has an air cylinder.

4. The substrate processing apparatus of claim 2, wherein the lifting/lowering device has an air cylinder.

5. (canceled)

6. The substrate processing apparatus of claim 3, wherein the lifting/lowering device has a lever structure.

7. The substrate processing apparatus of claim 4, wherein the lifting/lowering device has a lever structure.

8. The substrate processing apparatus of claim 1, further comprising:
a rotation shaft that is rotatably supported;
a housing that rotatably supports the rotation shaft;
a rotational driving device configured to rotatably drive the rotation shaft;
a support member that is fixed to the placing table and transmits rotation of the rotation shaft to the placing table while being engaging with the rotation shaft; and
a locking member fixed to the housing,
wherein when a contact surface of the freezing device is brought into contact with a surface to be contacted of the placing table, the engagement between the support member and the rotation shaft is released, and the support member is locked to the locking member.

9. The substrate processing apparatus of claim 2, further comprising:
a rotation shaft that is rotatably supported;
a housing that rotatably supports the rotation shaft;
a rotational driving device configured to rotatably drive the rotation shaft;
a support member that is fixed to the placing table and transmits rotation of the rotation shaft to the placing table while being engaging with the rotation shaft; and
a locking member fixed to the housing,
wherein when a contact surface of the freezing device is brought into contact with a surface to be contacted of the placing table, the engagement between the support member and the rotation shaft is released, and the support member is locked to the locking member.
